(19) United States
(12) Patent Application Publication
(10) Pub. No.: US 2025/0329610 A1
(43) Pub. Date: Oct. 23, 2025

(54) FLUID-COOLED POWER MODULE

(71) Applicant: SEMICONDUCTOR COMPONENTS INDUSTRIES, LLC, Scottsdale, AZ (US)

(72) Inventors: Seokbong KIM, Paju-si (KR); Byoungok LEE, Yeonsu-gu (KR); Yong LIU, Cumberland Foreside, ME (US)

(73) Assignee: SEMICONDUCTOR COMPONENTS INDUSTRIES, LLC, Scottsdale, AZ (US)

(21) Appl. No.: 18/641,733

(22) Filed: Apr. 22, 2024

(51) Int. Cl. H01L 23/473; H01L 23/367; H01L 23/433

(52) U.S. Cl. CPC H01L 23/473; H01L 23/3672; H01L 23/433

(57) ABSTRACT

Fluid-cooled power modules are disclosed, in which high power semiconductor chips are mounted on direct bonded metal (DBM) structures implemented with various cooling options. Such fluid-cooled power modules are suitable for use in electric vehicles or industrial applications. A cooling unit can be attached to the DBM structure, to provide a flow of cooling fluid that can be routed through a heat sink, or through channels formed in different layers of the DBM. A fluid pipe can route coolant through an encapsulant, to surround the semiconductor chips on multiple sides. A pair of DBMs can be included to provide double-sided cooling, or to accommodate multiple arrays of chips.

### TECHNICAL FIELD

This description relates to assembling and packaging semiconductor device modules, semiconductor device assemblies, and semiconductor devices. More specifically, this description relates to cooling techniques for high power semiconductor device modules.

### BACKGROUND

Semiconductor device assemblies, e.g., chip assemblies that include power semiconductor devices, can be implemented using multiple semiconductor dies, substrates (e.g., die attach pads (DAPs)), electrical interconnections, and a molding compound. Power transistors can include, for example, insulated-gate bipolar transistors (IGBTs), power metal-oxide-semiconductor field effect transistors (MOSFETs), and so forth. Electrical interconnections within a high-power semiconductor device module can include, for example, bond wires, conductive spacers, and conductive clips. A polymer molding compound can serve as an encapsulant to protect components of the device assembly. Such high-power chip assemblies, encapsulated as semiconductor device modules, can be used in various applications, including electric vehicles (EVs), hybrid electric vehicles (HEVs), and industrial applications.

### SUMMARY

In some aspects, the techniques described herein relate to a device, including: a fluid-cooled direct bonded metal structure, including: a first conductive layer, a second conductive layer, configured to support a flow of cooling fluid in contact with a surface area of the second conductive layer, and a non-conductive layer disposed between the first conductive layer and the second conductive layer; a heat sink coupled to the second conductive layer; a semiconductor die coupled to the fluid-cooled direct bonded metal structure; and a molding compound surrounding the semiconductor die and a portion of the fluid-cooled direct bonded metal structure.

In some aspects, the techniques described herein relate to a device, wherein the heat sink is part of a detachable cooling unit.

In some aspects, the techniques described herein relate to a device, further including a side heat slug coupling the second conductive layer to the first conductive layer.

In some aspects, the techniques described herein relate to a device, wherein the heat sink includes a base plate and a plurality of oblique fins extending out from the base plate at an acute angle.

In some aspects, the techniques described herein relate to a device, wherein the heat sink includes a base plate and a plurality of L-shaped fins extending out from the base plate at an acute angle.

In some aspects, the techniques described herein relate to a device, including: a fluid-cooled direct bonded metal structure configured with a channel, the fluid-cooled direct bonded metal structure including: a first conductive layer, a non-conductive layer, and a second conductive layer; a semiconductor die mounted on the fluid-cooled direct bonded metal structure; and a molding compound surrounding the semiconductor die and a portion of the fluid-cooled direct bonded metal structure.

In some aspects, the techniques described herein relate to a device, wherein the channel provides a first flow path through the second conductive layer.

In some aspects, the techniques described herein relate to a device, wherein the channel further provides a second flow path through the non-conductive layer.

In some aspects, the techniques described herein relate to a device, wherein the non-conductive layer includes a first ceramic plate and a second ceramic plate in which the channel is formed.

In some aspects, the techniques described herein relate to a device, wherein the channel further provides a second flow path through the molding compound to surround the semiconductor die.

In some aspects, the techniques described herein relate to a device, further including a U-shaped cooler pipe that provides a structure for the second flow path.

In some aspects, the techniques described herein relate to a device, wherein the channel provides a single flow path through the second conductive layer and through the non-conductive layer.

In some aspects, the techniques described herein relate to a device, wherein the channel provides a single flow path through the second conductive layer and through the molding compound to surround the semiconductor die.

In some aspects, the techniques described herein relate to a device, wherein the channel provides a single flow path through the non-conductive layer.

In some aspects, the techniques described herein relate to a device, wherein the semiconductor dies are mounted to at least one of the first conductive layer and the second conductive layer.

In some aspects, the techniques described herein relate to a cooling unit, including: a heat sink including an array of fins having a metal surface area, the array of fins configured to support a flow of cooling fluid in contact with the metal surface area; and a fluid container surrounding the heat sink.

In some aspects, the techniques described herein relate to a cooling unit, wherein the fins are L-shaped.

In some aspects, the techniques described herein relate to a cooling unit, wherein the fluid container includes aluminum.

In some aspects, the techniques described herein relate to a cooling unit, wherein the fluid container has the shape of a rectilinear box.

In some aspects, the techniques described herein relate to a cooling unit, wherein a top surface of the cooling unit is configured to receive a semiconductor module.

### BRIEF DESCRIPTION OF THE DRAWINGS

FIG. 1 is a high level pictorial perspective view of a fluid-cooled power module, according to some implementations of the present disclosure.

FIG. 2 is a cross sectional view of a semiconductor device module coupled to a heat sink for single-sided cooling, according to some implementations of the present disclosure.

FIG. 3 is a cross sectional view of a semiconductor device module coupled to a heat sink for double-sided cooling, according to some implementations of the present disclosure.

FIG. 4A is a cross sectional view of a semiconductor device module coupled to a heat sink with oblique fins, according to some implementations of the present disclosure.

FIG. 4B is a cross sectional view of a semiconductor device module coupled to a heat sink with L-shaped fins, according to some implementations of the present disclosure.

FIG. 5 is a cross-sectional view of a fluid-cooled power module featuring L-shaped fins, according to some implementations of the present disclosure.

FIGS. 6A-6D are plots of simulation results comparing performance of heat sinks having different fin configurations, according to some implementations of the present disclosure.

FIG. 7 is a high level pictorial perspective view of a fluid-cooled power module, according to some implementations of the present disclosure.

FIG. 8 is a cross sectional view of a semiconductor device module that includes a fluid-cooled direct bonded metal structure with multiple flow paths, according to some implementations of the present disclosure.

FIG. 9 is a cross sectional view of a semiconductor device module that includes a fluid-cooled direct bonded metal structure with a single flow path, according to some implementations of the present disclosure.

FIG. 10 is a cross sectional view of a fluid-cooled power module with multiple flow paths, according to some implementations of the present disclosure.

FIG. 11 is a perspective view of fluid channels formed in a pair of non-conductive layers, according to some implementations of the present disclosure.

FIG. 12 is an external pictorial perspective view of a packaged fluid-cooled power module, according to some implementations of the present disclosure.

FIG. 13 is a high level pictorial perspective view of a fluid-cooled power module that includes a cooler pipe, according to some implementations of the present disclosure.

FIG. 14 is an exploded view of the fluid-cooled power module shown in FIG. 13, according to some implementations of the present disclosure.

FIG. 15 is a cross sectional view of a semiconductor device module that includes a cooler pipe and multiple flow paths, according to some implementations of the present disclosure.

FIG. 16 is a cross sectional view of a semiconductor device module that includes a cooler pipe and a single flow path, according to some implementations of the present disclosure.

FIG. 17 is a cross sectional view of a fluid-cooled power module that includes a cooler pipe and a multiple flow paths, according to some implementations of the present disclosure.

FIG. 18 is a high level pictorial perspective view of a double-sided fluid-cooled power module, according to some implementations of the present disclosure.

FIG. 19 is a cross-sectional view of the double-sided fluid-cooled power module shown in FIG. 18, according to some implementations of the present disclosure.

FIG. 20 is a cross sectional view of a double-sided fluid-cooled semiconductor device module, according to some implementations of the present disclosure.

FIG. 21A is an exploded view of a packaged double-sided fluid-cooled power module, according to some implementations of the present disclosure.

FIG. 21B is an external perspective view of the packaged double-sided fluid-cooled power module shown in FIG. 21A, according to some implementations of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

It is important to dissipate heat generated within power semiconductor devices to limit possible adverse effects of overheating such as dimensional variations, variable operating characteristics, and differential thermal expansion. Overheating can compromise reliability of the devices and also wastes power, thereby increasing operating costs. Ineffective cooling of semiconductor devices may impose limitations on the design of power chip assemblies by constraining permissible power density, circuit density, or system speed. When heat is dissipated from a source (e.g., a power module) to a sink (e.g., a heat sink) by conduction, successful heat transfer can depend on the direct contact area between the source and the heat sink.

Some power modules include a direct bonded metal (DBM) structure that can be used, in part, to facilitate cooling of semiconductor devices. The DBM structure can include a first conductive layer, a second conductive layer, and a non-conductive layer made of an insulating material disposed between the first conductive layer and the second conductive layer. The second conductive layer can be, or can function as, a heat sink. In some implementations, multiple DBMs (e.g., two DBMs) can be used for double-sided cooling, or for cooling multiple arrays of high power chips. In some implementations, the second conductive layer can be coupled to a heat sink for single-sided cooling. In some implementations, the first conductive layer can be coupled to the heat sink via one or more side heat slugs. A heat sink for attachment to a DBM can be constructed as a metal base plate in which an array of fins is formed to accelerate heat dissipation by providing an increased surface area. However, at least one problem with such a solid metal heat sink is that the fins still may not dissipate heat fast enough.

This disclosure relates to implementations of a direct cooling approach in which the heat sink and/or the DBM interacts with a cooling fluid. In some implementations, the fins of the heat sink can be immersed in a cooling fluid. In some implementations, a metal heat sink with oblique fins is mounted to the underside of the DBM so that the fins are slanted toward a flow direction of the cooling fluid. Various fin configurations can be used to increase the surface area of the metal heat sink that is in contact with the cooling fluid for enhanced thermal performance.

In some implementations, heat dissipation can be facilitated by using a fluid-cooled DBM structure, with or without a heat sink, in which the flow path of the cooling fluid is routed through the DBM structure itself. In some implementations, the fluid-cooled DBM structure can be used instead of a heat sink. These implementations can bring the cooling fluid closer to the semiconductor die, e.g., adjacent to the high power integrated circuit chip where the heat is generated. In some implementations, the cooling fluid can be directed through a channel in the second conductive layer of the DBM structure. In some implementations, the channel may extend into the insulating layer of the DBM structure. In some implementations, a portion of the cooling fluid can flow through the insulating layer of the DBM while the remaining fluid flows through the second conductive layer or the DBM. In some implementations, all of the cooling fluid can flow through the insulating layer. In some implementations, some or all of the cooling fluid can be routed through the encapsulant e.g., a molding compound surrounding the semiconductor die, so that the cooling fluid surrounds at least a portion of the semiconductor die.

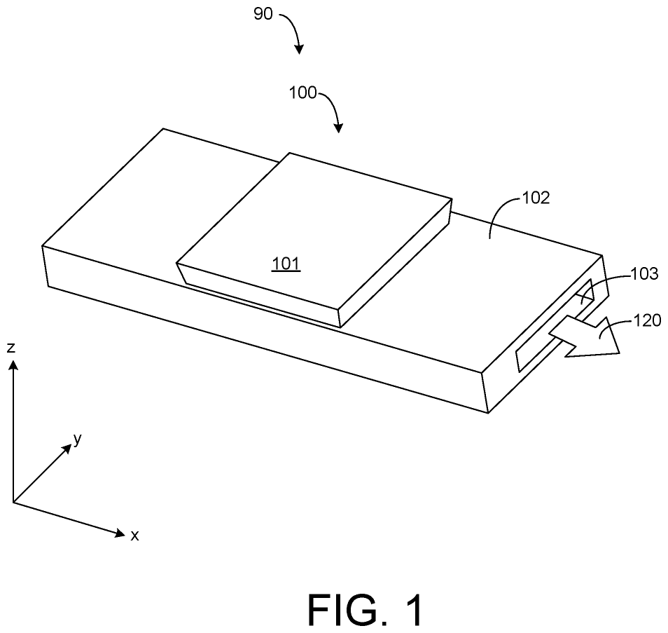

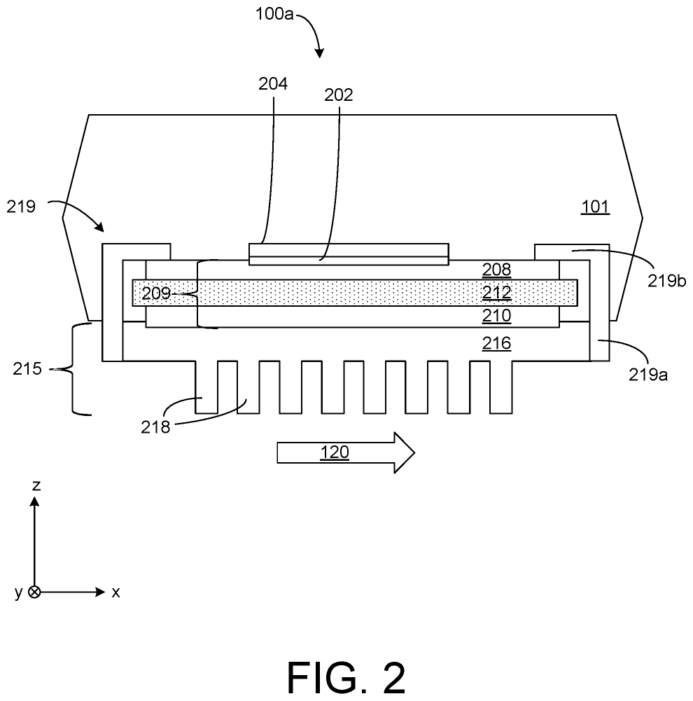

FIG. 1 is an exterior perspective view of a fluid-cooled power module 90, in accordance with some implementations of the present disclosure. The fluid-cooled power module 90 includes a semiconductor device module 100 mounted on (e.g., attached to, coupled to) a heat dissipation structure 102. In some implementations, the semiconductor device module 100 is a high power semiconductor device module. The semiconductor device module 100 is packaged in an encapsulant 101. The heat dissipation structure 102 provides containment for flow of a cooling fluid, e.g., a water jacket, wherein the flow direction is indicated by the arrow 120. A slot 103 in the end of the heat dissipation structure 102 is shown in FIG. 1, through which the cooling fluid can flow during operation of the fluid-cooled power module 90. In some implementations as shown in FIGS. 2-5 and described below, the cooling fluid interacts with an internal heat sink that is attached to the semiconductor device module 100 and extends below the encapsulant 101 into the heat dissipation structure 102.

FIG. 2 is a cross-sectional view of a semiconductor device module 100a, in accordance with some implementations of the present disclosure. The semiconductor device module 100a is possible implementation of the semiconductor device module 100 within the fluid-cooled power module 90 shown in FIG. 1. In FIG. 2, interior elements of the semiconductor device module 100a are shown without the heat dissipation structure 102. The semiconductor device module 100a includes a die attach (DA) 202 One or more electronic components, e.g., semiconductor dies or chip assemblies 204 (one shown), can be in contact with the DA 202. The chip assemblies 204 may include high power chip assemblies that generate heat and may cause heat accumulation within the semiconductor device module 100a. The DA 202 can be integral to, or attached to, a first conductive layer 208 of a direct bonded metal (DBM) structure 209. The DBM structure 209 can further include a second conductive layer 210 and non-conductive layer 212. The semiconductor device module 100a further includes the encapsulant 101 and a heat sink 215 having a base plate 216, fins 218 (8 shown), and, optionally, side heat slugs 219 (two shown). The heat sink 215, or portions thereof, can be in contact with the cooling fluid. The heat sink 215 provides single-sided cooling for the semiconductor device module 100a.

In some implementations, the DBM structure 209 can be a direct bond copper (DBC) type structure, a direct plating copper (DPC) type structure, or a direct bond aluminum (DBA) type structure. The DBM structure 209 may be referred to as a heat spreader that provides single-sided cooling of the chip assemblies 204. In some implementations, the DBM structure 209 has a thickness in a range of about 0.5 mm to about 3.0 mm. In some implementations, the DBM structure 209 is designed as a three-layer DBM structure that includes the non-conductive layer 212 sandwiched between the first conductive layer 208 and the second conductive layer 210. In some implementations, the non-conductive layer 212 serves as a thermal mass disposed between the two outer metal layers to draw in and absorb heat. The non-conductive layer 212 may also provide electrical insulation between the first conductive layer 208 and the second conductive layer 210 of the DBM structure 209.

In some implementations, the first conductive layer 208 and the second conductive layer 210 can be, or can include, a metal layer (e.g., a copper layer, a copper alloy layer) that is formed on (e.g., bonded to, sputtered on, diffused onto to, heat-formed on) the non-conductive layer. The first conductive layer 208 can be coupled to a first side of the non-conductive layer 212, and the second conductive layer 210 can be coupled to a second side of the non-conductive layer 212. The first conductive layer 208 can be, or can include, a metal redistribution layer (RDL) pattern on which to mount (or couple) semiconductor chips using die attach, wherein the DA can be solder and/or metal sintering including silver (Ag) sintering. In some implementations, the non-conductive layer 212 can include a ceramic material, e.g., silicon nitride (Si₃N₄) or aluminum oxide (Al₂O₃), Si₃N₄ being a significantly more expensive ceramic material than Al₂O₃. The first conductive layer 208 or the second conductive layer 210 can be referred to as an upper conductive layer or as a lower conductive layer depending on the orientation of the device.

In some implementations, the die attach 202 can be formed by the first conductive layer 208 of the DBM structure 209. In some implementations, the non-conductive layer 212 and/or the second conductive layer 210 of the DBM structure 209 can have a larger footprint than the DA 202.

The chip assembly 204 can be attached to, e.g., mounted on, or coupled to, a top metal surface of the DBM structure 209 by the DA 202 using solder or a sintering layer e.g., a conductive epoxy, a silver (Ag) or copper (Cu) sintering material, and/or a conductive adhesive. In some implementations that include multiple chip assemblies 204, first and second chip assemblies 204 can be coupled to the DAP 202 by two different bonding agents. For example, in some implementations, a first chip assembly 204 can be attached to the metal pattern of the DBM structure 209 by sintering, while a second chip assembly 204 is attached by DA to the metal pattern of the DBM structure 209 using conductive polyimide tape.

In some implementations, the chip assembly 204 can include for example, a controller and/or an insulated gate bipolar transistor (IGBT). In some implementations that include multiple chip assemblies 204, such chip assemblies can include an IGBT and a controller configured to control the IGBT. The controller can also serve as a protection device for the IGBT. For example, the controller can provide temperature protection and/or over-voltage protection for the IGBT. The controller can also limit the amount of current delivered to the IGBT. In some implementations, the controller can be configured to monitor the IGBT. In some implementations, other types of semiconductor dies, e.g., silicon MOSFETs, silicon carbide (SiC) MOSFETs, diodes, and so forth, can be used as one or more of the chip assemblies 204. In some implementations, a SiC MOSFET can be substituted for the IGBT. In some implementations, fast recovery diodes (FRDs) may be used in conjunction with power transistors.

The chip assemblies 204 can be fabricated on various types of semiconductor substrates, e.g., semiconductor wafers, for example, silicon (Si), silicon carbide (SiC), gallium (Ga), gallium nitride (GaN), aluminum gallium nitride (AlGaN), gallium arsenide (GaAs), aluminum gallium arsenide (AlGaAs), indium phosphide (InP), glass substrates, sapphire substrates, and so on. In general, any type of semiconductor chip can be fabricated on any type of substrate.

In some implementations, different chip assemblies 204 can be fabricated on different substrates in a hybrid configuration. For example, an IGBT chip assembly 204 can be fabricated on a SiC substrate, while a controller chip assembly 204 can be fabricated on a silicon substrate. In some implementations as described herein, multiple chip assemblies 204 can be fabricated on the same substrate, e.g., on a SiC substrate, suitable for high power applications.

In some implementations, the encapsulant 101 can include a molding material (e.g., a molding compound). For example, the encapsulant 101 can include a molding material such as a polymer material (e.g., an epoxy molding compound (EMC)) that serves to seal and protect the various components of the semiconductor device module 100a. Encapsulation can be accomplished by, for example, a process of injection molding or a process of transfer molding. In some implementations, the encapsulant 101 can expose the DBM structure 209 through openings in the encapsulant 101 (not shown). In some implementations, the DBM structure 209 can be disposed in an opening in the encapsulant 101 so that the second conductive layer 210 is exposed on the bottom of the semiconductor device module 200. In some implementations, the second conductive layer 210 is in contact with the heat sink 216 so as to dissipate heat produced by the semiconductor device module 100a. In some implementations, the side heat slug 219 couples the first conductive layer 208 to the heat sink 216 to draw heat away from the chip assembly 204 via the die attach pad 202.

In some implementations, the heat sink 215 can be coupled to the second conductive layer 210, to enhance single-sided direct cooling of the semiconductor device module 100a. Joining the heat sink 215 to the DBM can be accomplished using, for example, a metal-to-metal attachment technique such as sintering, soldering, and so forth. In some implementations, an epoxy or other bonding agent can be used to attach the heat sink. In some implementations, the heat sink 215 includes the base plate 216 and a plurality of fins 218. The heat sink 215 can include one or more high-conductivity metals, e.g., copper (Cu). The base plate 216 conducts heat away from the semiconductor device module 100a, to be dissipated by the fins 218. In some implementations, the base plate 216 is aligned with the x-y plane as shown in FIG. 2.

In the example shown, the fins 218 are straight fins having a rectangular profile however, the fins 218 are not so limited. Other shapes for the fins 218 include cylinders having circular, elliptical, triangular, or rhombus-shaped cross-sections, wavy structures, e.g., serpentine structures, and so forth. The fins 218 can be attached to, e.g., contiguous with, the base plate 216, or the fins 218 together with the base plate 216 can be portions of the heat sink 215, e.g., as a unitary heat sink. In some implementations, the fins 218 can extend downward, in a direction transverse to the length of the base plate 216, along the −z direction as shown in FIG. 2.

The side heat slugs 219, if used, may extend along both sides of the base plate 216, vertically through the encapsulant 101, and horizontally to attach to a top surface of the first conductive layer 208, the side heat slugs 219 thus forming a pair of L-shaped structures having a vertical side heat slug portion 219a and a horizontal side heat slug portion 219b. The side heat slugs 219 assist in conducting heat between the first conductive layer 208 and the base plate 216 to increase efficiency of the heat sink 215. The side heat slugs 219 can be made of the same metal or a different metal than the base plate 216, the fins 218, and the metal layers of the DBM structure 209, e.g., copper, aluminum, or an aluminum-copper (AlCu) alloy. The side heat slugs 219 can also provide further structural stability to the DBM structure 209 and the heat sink 215.

In some implementations, the fins 218 can be partially or fully immersed in a cooling fluid during operation of the fluid-cooled power module 90. In some implementations, the cooling fluid flows past the fins 218 in a direction indicated by the arrow 120. In some implementations, the cooling fluid can be still, e.g., not flowing, or the cooling fluid can flow in another direction. The fins 218 increase the surface area of the heat sink 215 that is in contact with the cooling fluid, this increasing the rate of heat dissipation. The cooling fluid can be any type of fluid, e.g., the cooling fluid can be in the form of a liquid, a vapor, a gel, an aerosol, or other type of fluid. Depending on the position of the heat dissipation structure 102 relative to the semiconductor device module 100a and the volume, e.g., depth, and/or the viscosity of the cooling fluid, the cooling fluid can surround various elements of the heat sink 215. For example, the cooling fluid may surround portions of the fins 218, all of the fins 218, the fins 218 together with a portion of the base plate 216, or the fins 218 together with all of the base plate 216 and portions of the side heat slugs 219.

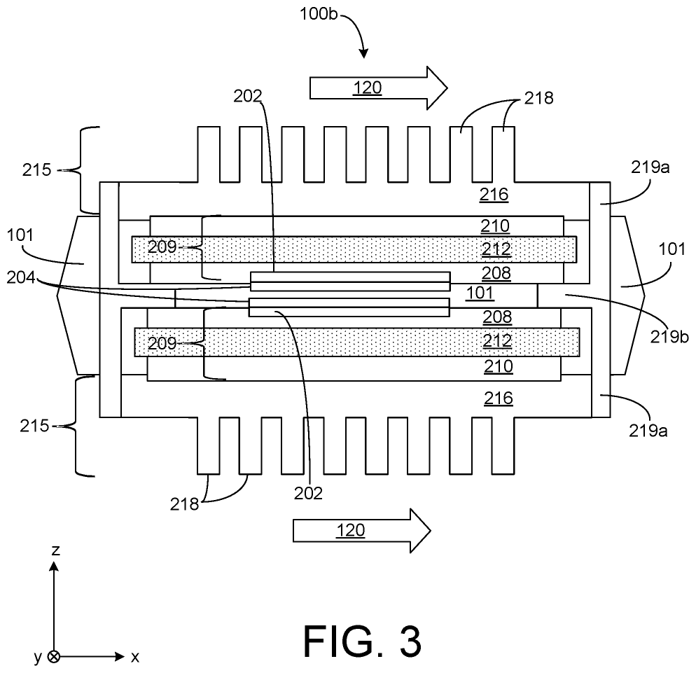

FIG. 3 is a cross-sectional view of a double-sided semiconductor device module 100b, in accordance with some implementations of the present disclosure. The double-sided semiconductor device module 100b is another possible implementation of the semiconductor device module 100 shown in FIG. 1. The double-sided semiconductor device module 100b includes elements similar to those shown in FIG. 2 and described with respect to the semiconductor device module 100a . . . . The double-sided semiconductor device module 100b includes a first DAP 202 in contact with a first chip assembly 204 and a second DAP 202 in contact with a second chip assembly 204. The first DAP 202 is coupled to a first DBM structure 209 in which the second conductive layer 210 is attached to a first heat sink 215. The second DAP 202 is coupled to a second DBM structure 209 in which the second conductive layer 210 is attached to a second heat sink 215. The first heat sink 215 and the second heat sink 215 can be in contact with flow of a cooling fluid indicated by the arrow 120. The heat sinks 215 provide double-sided cooling for the chip assemblies 204. In similar fashion as the semiconductor device module 100a, the double-sided semiconductor device module 100b includes the encapsulant 101 and, optionally, a pair of side heat slugs 219 forming a T-shape that couple the first conductive layers 208 of the first and second DBMs 209 to respective base plates 216.

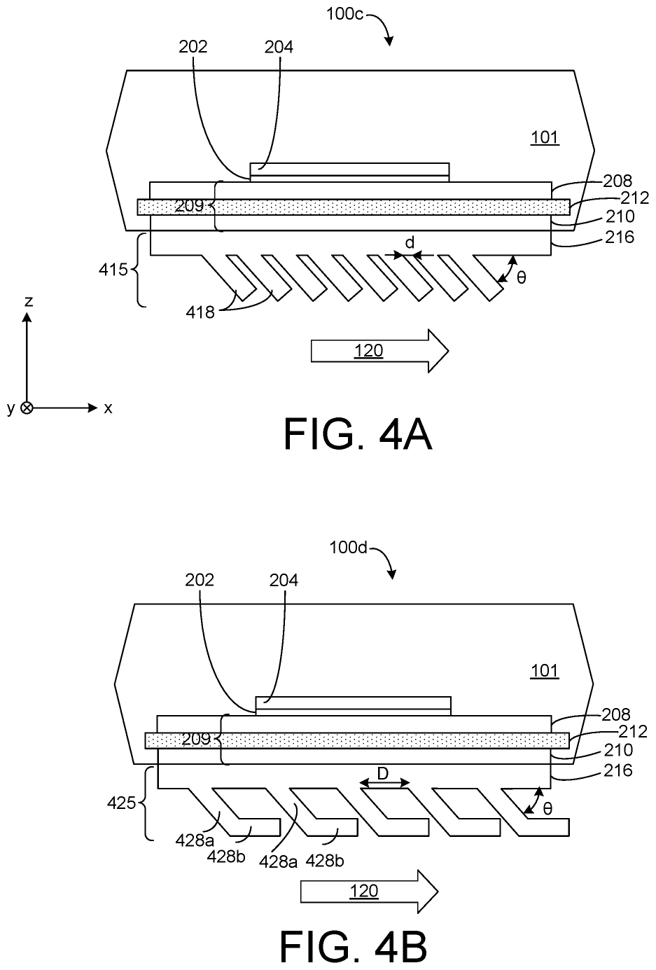

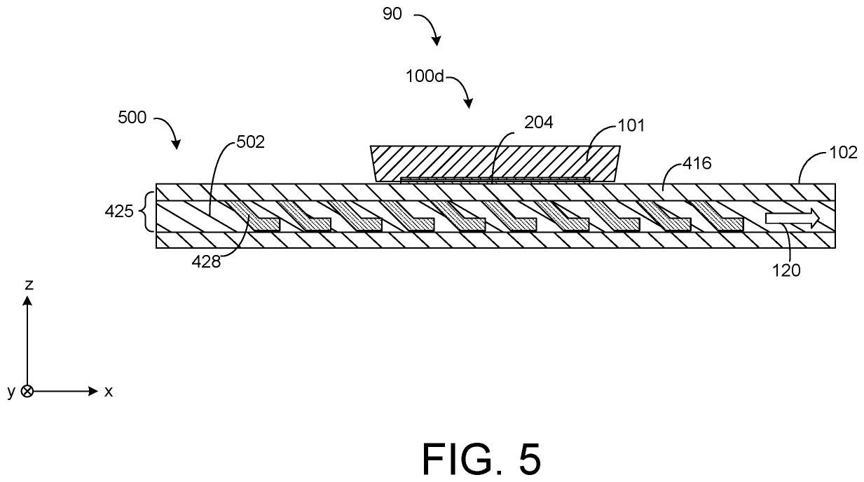

FIGS. 4A and 4B illustrate other heat sink configurations, in accordance with some implementations of the present disclosure. FIG. 4A shows a semiconductor device module 100c as another possible implementation of the semiconductor device module 100 shown in FIG. 1. The semiconductor device module 100c is similar to the semiconductor device module 100a, except that the semiconductor device module 100c features a heat sink 415 characterized by oblique fins 418 (8 shown) spaced apart by a distance d.

FIG. 4B shows a semiconductor device module 100d as another possible implementation of the semiconductor device module 100 shown in FIG. 1. The semiconductor device module 100d is similar to the semiconductor device module 100c, except that the semiconductor device module 100d features a heat sink 425 characterized by L-shaped fins 428 (5 shown) spaced apart by a distance D. As in the case of the semiconductor device module 100, the semiconductor device module 100c and the semiconductor device module 100d can be augmented with a second DBM and an additional heat sink coupled to a metal layer of the second DBM, to provide double-sided cooling, in similar fashion as shown in FIG. 3.

In some implementations, both the oblique fins 418 and the L-shaped fins 428 can be angled in the direction of the flow of the cooling fluid. The orientation of the oblique fins 418 or the L-shaped fins 428 can be at an acute angle θ to the +x direction, that is between 0 degrees and 90 degrees from the underside of the base plate 216. Each L-shaped fin 428 includes an angled section 428a that resembles the oblique fin 418 and an additional straight section 428b that further increases the surface area of metal in contact with the cooling fluid. The additional straight section 428b is accommodated by a wider spacing D between the L-shaped fins 428 than the narrow spacing d between the oblique fins 418. Consequently, fewer of the L-shaped fins 428 can be attached to the base plate 416.

The heat sink 415 shown in FIG. 4A and the heat sink 425 shown in FIG. 4B are presented without the side heat slugs 219. However, in some implementations, the side heat slugs 219 can be added to either semiconductor device module 100c or semiconductor device module 100d.

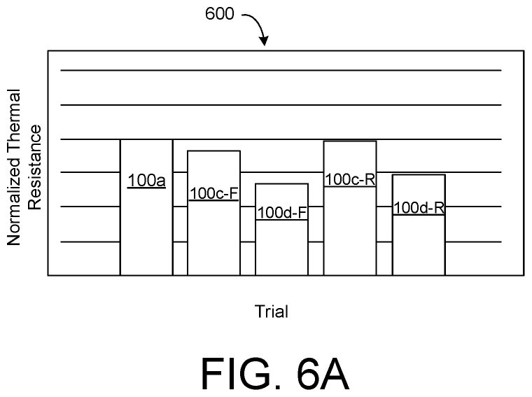

FIG. 5 is a cross-sectional view of the fluid-cooled power module 90, in accordance with some implementations of the present disclosure. In FIG. 5, the semiconductor device module 100d is implemented with the heat sink 425 that includes the L-shaped fins 428, as an example. In other implementations, different semiconductor device modules, e.g, the semiconductor device modules 100a or 100c, having different fin configurations, can be substituted for the semiconductor device module 100d. The heat dissipation structure 102, together with the heat sink 425 form a cooling unit 500, e.g., a detachable cooling unit. In some implementations, the cooling unit 500 can be detachable from the semiconductor device module 100d. The L-shaped fins 428 are angled in the flow direction of a cooling fluid 502 that passes through the heat dissipation structure 102. The fluid flow is indicated by the arrow 120, e.g., as shown in the +x direction. In this example, the L-shaped fins 428 are submerged in the cooling fluid 502. In some implementations, as shown in FIG. 5, the heat sink 425 can extend out sideways, beyond lateral boundaries of the encapsulant 101.

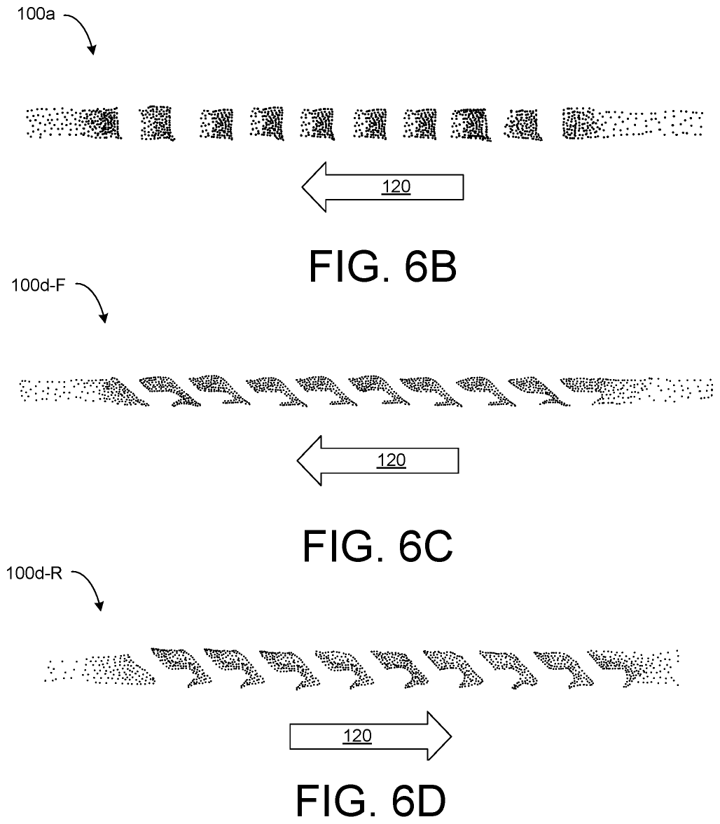

FIG. 6A is a plot 600 of simulation results comparing the thermal performance of the fluid-cooled power module 90 implemented with different semiconductor device modules 100, e.g., the semiconductor device module 100a, the semiconductor device module 100c, and the semiconductor device module 100d. In each simulation run, the semiconductor device module under test is established as a structural input, and is subjected to a simulated flow in which the cooling fluid interacts with the heat sink 215 (straight fins), the heat sink 415 (oblique fins), or the heat sink 425 (L-shaped fins), respectively. In the simulation, the chip assembly 204 within each semiconductor device module operates at a power level of 10 Watts. Flow parameters that provide additional inputs to the simulation include a cooling fluid composition having a 50/50 mixture of ethylene glycol and water; a cooling fluid temperature of 55 degrees C.; and a cooling fluid flow velocity of 0.31 m/s. Aluminum is specified as the material of the heat dissipation structure 102.

The plot 600 is in the form of a bar chart comparing the effectiveness of the three corresponding heat sink configurations: straight fins 218, oblique fins 418, and L-shaped fins 428, interacting thermally with the cooling fluid flowing in a forward direction (F), e.g., in the +x direction, or in a reverse direction (R), e.g., in the −x direction. The flow direction (F) or (R) is relative to the slant of the fins, that is, forward is aligned with the slant of the fins and reverse is opposite to the slant of the fins. A total of five simulation trials are shown in FIG. 6. The simulation results compare a computed normalized thermal resistance as the output of each trial, wherein a lower value of thermal resistance indicates more, e.g., faster, cooling of the heat sink, and is therefore preferable to a higher value. According to the simulation, the thermal resistance of the semiconductor device module 100a having straight fins 218 was the highest, while the thermal resistance of the semiconductor device module 100d L-shaped fins 428 was the lowest. Forward flow was associated with lower thermal resistance than reverse flow. It can be concluded from the five simulation trials shown in FIG. 6A that a forward flow of the cooling fluid over the L-shaped fins 428 is the most effective heat sink, and the straight fins 218 are the least effective fin configuration. According to the simulation, the improvement of the semiconductor device module 100d over the semiconductor device module 100a is about 7%., compared to about a 2% improvement associated with the semiconductor device module 100c.

FIGS. 6B, 6C, and 6D show fluid simulation scatter plots of fluid velocity in accordance with some implementations of the present disclosure. The fluid simulations track the flow velocity of the cooling fluid, as the cooling fluid interacts with the straight fins (100a) shown in FIG. 6B, the L-shaped fins (100d) with flow in the forward direction shown in FIG. 6C, and the L-shaped fins (100d) with flow in the reverse direction shown in FIG. 6D. The plots show side views, e.g., profiles, of the respective fin configurations. The darker areas indicate higher fluid velocity, which is more desirable because at a higher velocity, the cooling effect of the fluid is greater. It is noted that the scale of the results shown in FIG. 6B is different from the scale of the results shown in FIG. 6C and FIG. 6D. According to the simulation, the maximum velocity of the fluid flowing around the straight fins, as shown in FIG. 6B was about 20% slower than the maximum velocity of the fluid flowing around the L-shaped fins, as shown in FIGS. 6C and 6D. The maximum velocity of the reverse flow shown in FIG. 6D is about 5% slower than the maximum velocity of the forward flow shown in FIG. 6C. The simulation also provides a qualitative illustration of how the shape of the fins impedes fluid flow. The darker areas indicate regions where the fluid is impeded and the lighter areas indicate regions where the fluid flows freely, but at a reduced flow rate.

Temperature profiles obtained from the simulations show that the temperature of the fluid-cooled power module 90 implemented with L-shaped fins is about 4.5% cooler than the fluid-cooled power module 90 implemented with straight fins. According to the simulation, the flow direction makes about a 1% difference in the temperature of the fluid-cooled power module 90, with the forward flow direction resulting in a slightly cooler temperature of the fluid-cooled power module 90 than the reverse flow direction.

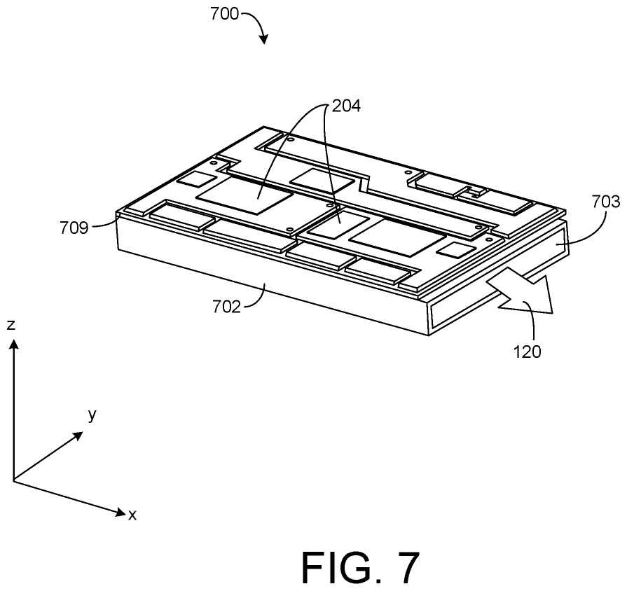

FIG. 7 is an exterior perspective view of a fluid-cooled power module 700, in accordance with some implementations of the present disclosure. The fluid-cooled power module 700 includes a semiconductor device module mounted on, e.g., attached to, a heat dissipation structure 702. The semiconductor device module is shown unencapsulated in FIG. 7. In some implementations, the semiconductor device module is a high power semiconductor device module that features a fluid-cooled DBM structure 709 instead of a heat sink having fins. The fluid-cooled DBM structure 709 supports chip assemblies 204.

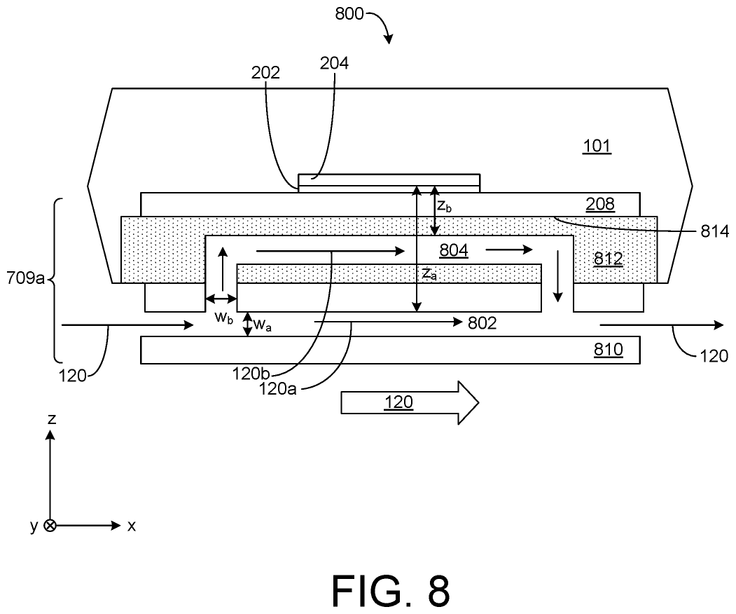

The heat dissipation structure 702 serves as a fluid container, e.g., a water jacket. The heat dissipation structure 702 provides containment for flow of a cooling fluid in a direction indicated by the arrow 120. In some implementations, the heat dissipation structure 702 can have the shape of a rectangular box. A slot 703 in one end of the heat dissipation structure 702 is shown in FIG. 7, through which the cooling fluid can flow during operation of the fluid-cooled power module 700. In some implementations as shown in FIGS. 8, 9, and 12, and as described below, the cooling fluid can be channeled to flow from the heat dissipation structure 702 along various routes through portions of the fluid-cooled DBM structure 709.

FIG. 8 is a cross-sectional view of a semiconductor device module 800, in accordance with some implementations of the present disclosure. The semiconductor device module 800 includes a fluid-cooled DBM structure 709a as a possible implementation of the fluid-cooled DBM structure 709 shown in FIG. 7. The fluid-cooled DBM structure 709a provides internal cooling by routing the cooling fluid through multiple channels. In some implementations, the semiconductor device module 800 can include a first channel 802 through the second conductive layer 810 and a second channel 804 through the non-conductive layer 812, e.g., through the non-conductive layer of the fluid-cooled DBM structure 700a. The non-conductive layer 812 can be thicker than the non-conductive layer 212 shown in FIGS. 2, 3, 4A, and 4B, to accommodate the second channel 804. The first channel 802 provides a bypass through the fluid-cooled DBM structure 709a.

The general direction of fluid flow through the fluid-cooled DBM structure 800 is shown by the arrow 120. In some implementations, a first portion of the cooling fluid can be routed horizontally in the +x direction, along a direct flow path 120a, e.g., a substantially straight path, or a linear path through the fluid-cooled DBM structure 709a. The direct flow path 120a is provided by the first channel 802 in the non-conductive layer 812, as indicated by the arrows in FIG. 8. A second portion of the cooling fluid can be routed around an indirect flow path 120b, e.g., a circuitous path, a curved path, or a U-shaped path, through the fluid-cooled DBM structure 709a. The indirect flow path 120b is provided by the second channel 804 in the non-conductive layer 812. The indirect flow path 120b is contiguous from end to end, as is the direct flow path 120a. In some implementations, the second channel 804 can be a U-shaped channel such that the indirect flow path 120b includes at least one 90-degree turn. Accordingly, the second portion of the cooling fluid initially flows along a horizontal path in the +x direction to enter the second conductive layer 810. The second portion can then be diverted upward around a first turn of about 90 degrees in the indirect flow path 120b, into the non-conductive layer 812 through the second channel 804 along a vertical flow path in the +z direction. Then the second portion can be diverted around a second turn of about 90 degrees, horizontally in the +x direction near an upper boundary 814 of the non-conductive layer 812. Finally, the second portion can be diverted around a third turn of about 90 degrees, downward in the −z direction to join with the first portion of the cooling fluid. In some implementations, some or all of the turns of the indirect flow path 120b may not be at right angles, for instance, some of the turns can be slanted at about 45 degrees, or at some other angle. In some implementations, turn angles along the indirect flow path 120b can all be different. Once the first and second portions of the cooling fluid are re-joined, both portions of the cooling fluid can then flow together, horizontally in the +x direction shown by the arrow 120, to exit the second conductive layer 810. As the cooling fluid absorbs heat along its flow paths, and then exits the DBM, the cooling fluid carries heat out of the non-conductive layer 812, thus cooling the semiconductor device module 800.

Because the second portion of the cooling fluid is diverted to flow horizontally through the second channel 804, near the upper boundary 814 of the non-conductive layer 812, the second portion is brought in close proximity, e.g., at a short vertical distance z_{b} to the chip assemblies 204. Consequently, the second portion of the cooling fluid can absorb more heat generated by the chip assemblies 204 than the first portion 102a can absorb at a long vertical distance zₐ from the chip assemblies 204 while flowing through the first channel 802. Thus, splitting the flow path to bring some of the cooling fluid closer to the chip assemblies 204, e.g., along the indirect flow path 120b through the second channel 804, will cool the semiconductor device module 800 more quickly and efficiently than flowing all of the cooling fluid along the direct flow path 120a, through the first channel 802. By adjusting the position of the horizontal portion of the channel 804 to reduce the vertical distance z_{b} the cooling efficiency of the semiconductor device module 800 can be further increased.

A volume of cooling fluid, e.g., an amount of the second portion, that enters the second channel 804, relative to the volume of cooling fluid, e.g., an amount of the first portion, that enters the first channel 802, can be influenced by the relative widths of the two channels, e.g., a channel width wₐ of the first channel 802 relative to a channel width w_{b} of the second channel 804. In some implementations, the channel width w_{b} of the second channel 804 can be about half the width of the non-conductive layer 812. In some implementations, the length of the second channel 804 is about 7% to about 10% of the length of the non-conductive layer 812. In some implementations, an area of the second channel 804 covers about half the area of the DBM. When w_{b} is wider than wₐ, the second portion of the cooling fluid that flows along the indirect flow path 120b in the second channel 804 may be larger, e.g., by volume, than the first portion of the cooling fluid that flows through the first channel 802. In some implementations, when w_{b} is wider than wₐ a flow rate of the second portion within the second channel 804 can exceed a flow rate of the first portion within the first channel 802. In some implementations, when w_{b} is wider than wₐ a pressure of the first portion within the first channel 802 can exceed a pressure of the second portion within the second channel 804. By adjusting one or more of the flow rate, the pressure, or the volume of the second portion relative to the first portion, the cooling efficiency of the semiconductor device module 800 can be increased.

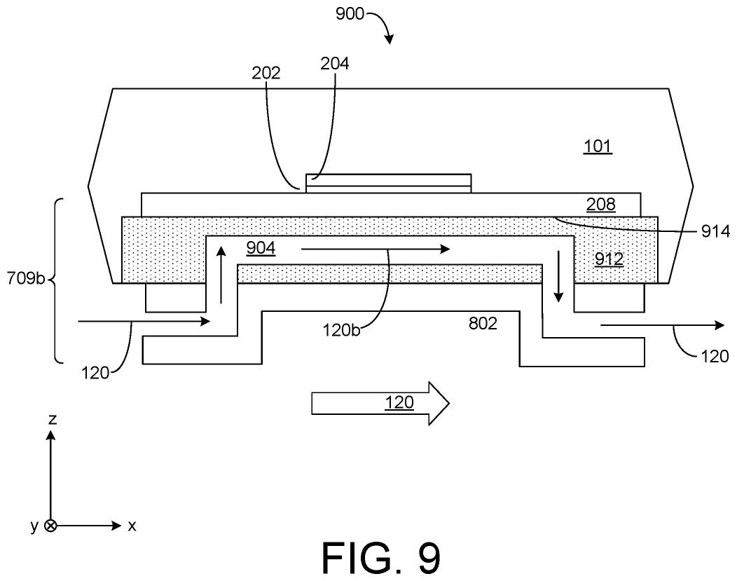

FIG. 9 is a cross-sectional view of a semiconductor device module 900, in accordance with some implementations of the present disclosure. The semiconductor device module 900 includes a fluid-cooled DBM structure 709b as a possible implementation of the fluid-cooled DBM structure 709 shown in FIG. 7. Similar to the semiconductor device module 800 shown in FIG. 8, the semiconductor device module 900 also provides cooling by routing the cooling fluid through a fluid-cooled DBM structure, e.g., the fluid-cooled DBM structure 709b. However, instead of splitting the cooling fluid into two portions along different flow paths within two different channels, in the semiconductor device module 900, all of the cooling fluid is routed through the indirect flow path 120b through a non-conductive layer 912 of the fluid-cooled DBM structure 709b. Consequently, the pressure of the fluid in the fluid-cooled DBM structure 709b may be greater than the pressure of the fluid in the second channel 804 of the fluid-cooled DBM structure 709a shown in FIG. 8, because there is no bypass provided in the fluid-cooled DBM structure 709b. The non-conductive layer 912 can be thinner than the non-conductive layer 812 shown in FIG. 8, since the fluid-cooled DBM structure 900 has a single channel 904.

The indirect flow path 120b through the fluid-cooled DBM structure 709b is provided by a U-shaped channel 904 that brings the cooling fluid in close proximity to the chip assemblies 204. The cooling fluid can be routed initially along a horizontal section of a flow path in the +x direction to enter the non-conductive layer 912. The cooling fluid can then be directed upward along a vertical section of the flow path in the +z direction, then horizontally in the +x direction near the upper boundary 914 of the non-conductive layer 812, then downward in the −z direction and then horizontally in the +x direction to exit the non-conductive layer 912. As the cooling fluid absorbs heat along its circuitous flow path 120b through the U-shaped channel 904 in the non-conductive layer 912, and then exits the non-conductive layer 912, the cooling fluid carries heat out of the non-conductive layer 912, thus cooling the semiconductor device module 900.

Because all of the cooling fluid is directed to flow horizontally near the upper boundary 914 of the non-conductive layer 912, a full volume of the cooling fluid is brought in close proximity to the chip assemblies 204. Consequently, the cooling fluid can absorb more heat generated by the chip assemblies 204 than if some of the cooling fluid was routed farther away from the chip assemblies 204. Thus, the configuration shown in FIG. 9 would be expected to cool the semiconductor device module 900 more quickly and efficiently than routing only a portion of the cooling fluid close to the chip assemblies 204 as in the configuration shown in FIG. 8.

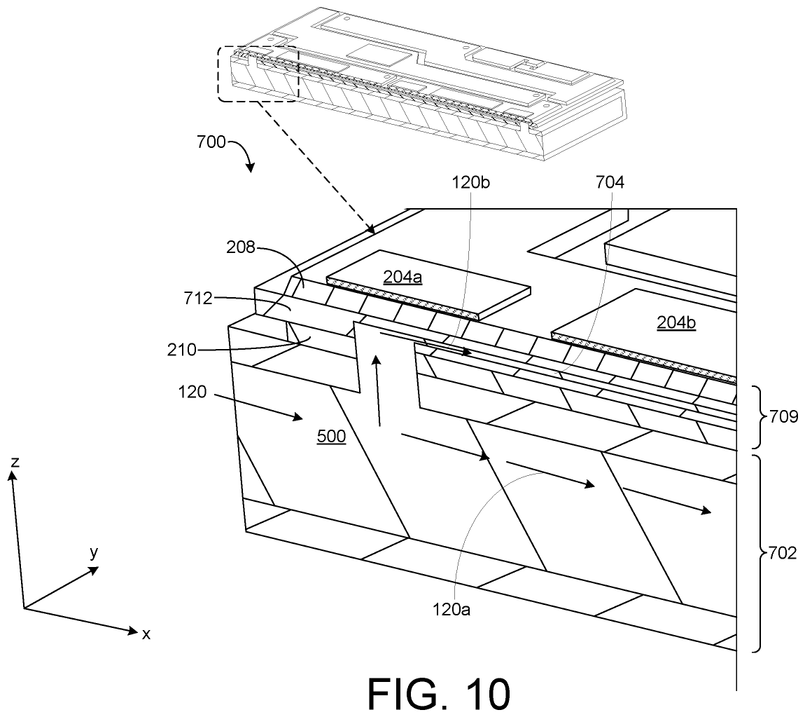

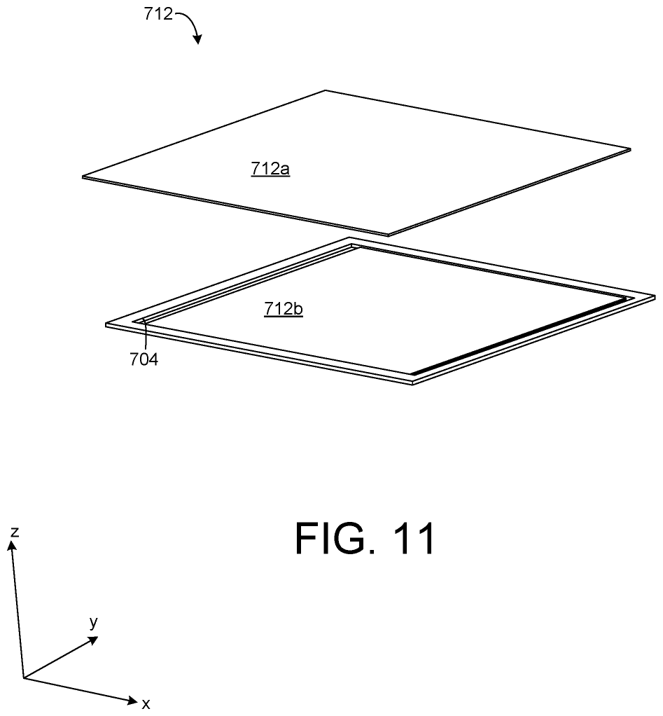

FIG. 10 is a cross-sectional view of the fluid-cooled power module 700 shown in FIG. 7, in accordance with some implementations of the present disclosure. The cross-sectional view shows interior elements of the fluid-cooled DBM structure 709 and interior elements of the heat dissipation structure 702. The first conductive layer 208 of the fluid-cooled DBM structure 709 is patterned e.g., by etching, so that remaining portions of the first conductive layer 208 support the chip assemblies 204 (two shown, 204a and 204b). FIG. 10 shows the cooling fluid 502 entering the heat dissipation structure 902 along a path 120. A first portion of the cooling fluid 502 flows along a direct flow path 120a through the heat dissipation structure 702, while a second portion of the cooling fluid 502 flows along a indirect flow path 120b through the fluid-cooled DBM structure 709. The indirect flow path 120b directs the second portion through a channel 704 in a non-conductive layer 712 of the fluid-cooled DBM structure 709. The multiple fluid paths shown in FIG. 11 are similar to those shown in FIG. 8, except the direct flow path 120a in FIG. 11 is through the heat dissipation structure 702, whereas the direct flow path 120a in FIG. 8 is within the second conductive layer 810.

FIG. 11 is a perspective view of the non-conductive layer 712 of the fluid-cooled DBM structure 709 within the fluid-cooled power module 700, in accordance with some implementations of the present disclosure. The non-conductive layer 712 of the fluid-cooled DBM structure 709 can be configured as, for example, the non-conductive layer 812 of the fluid-cooled DBM structure 709a, or the non-conductive layer 912 of the fluid-cooled DBM structure 709b. In some implementations, the non-conductive layer 712 includes a first ceramic plate 712a and a second ceramic plate 712b. In some implementations, the first ceramic plate 712a is flat, e.g., having a uniform surface. In some implementations, the second ceramic plate 712b has an extruded surface that includes a channel 704 through which the cooling fluid can be routed as shown in FIG. 10. The first ceramic plate 712a and the second ceramic plate 712b can be attached to one another to form the non-conductive layer 712. In some implementations, the first and second ceramic plates can be insulating plates of similar form, but made of another material. In some implementations, the channel 704 can be formed in an underside of the first ceramic plate 712a while the second ceramic plate 712b has planar surfaces. In some implementations, the channel 704 can be formed, e.g., distributed, in both the underside of the first ceramic plate 712a and a top surface of the second ceramic plate 712b.

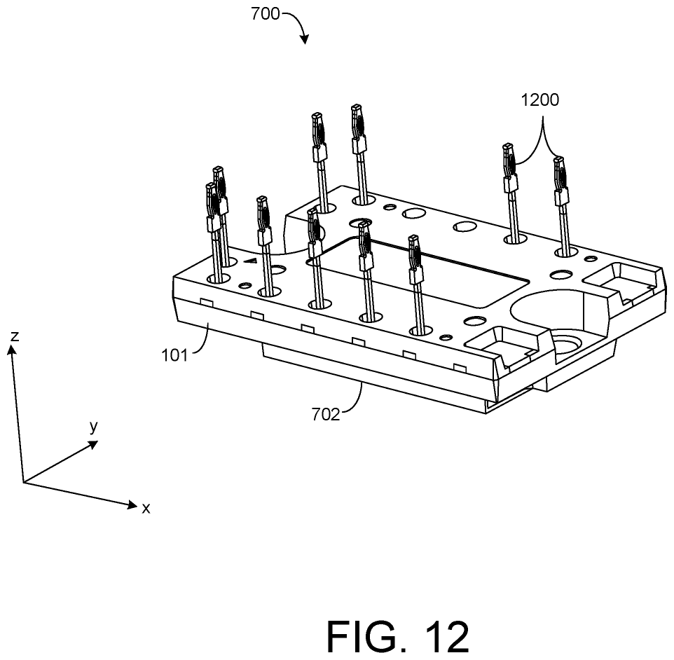

FIG. 12 illustrates the fluid-cooled power module 700 following packaging, in accordance with some implementations of the present disclosure. As shown in FIG. 12, the semiconductor device module has been enclosed by the encapsulant 101, e.g., an epoxy molding compound (EMC). The heat dissipation structure 702 is not encapsulated and extends out from under the encapsulant 101. Conduction pins 1200 extend upward from the semiconductor device module through the encapsulant 101 to provide electrical connectivity to external components.

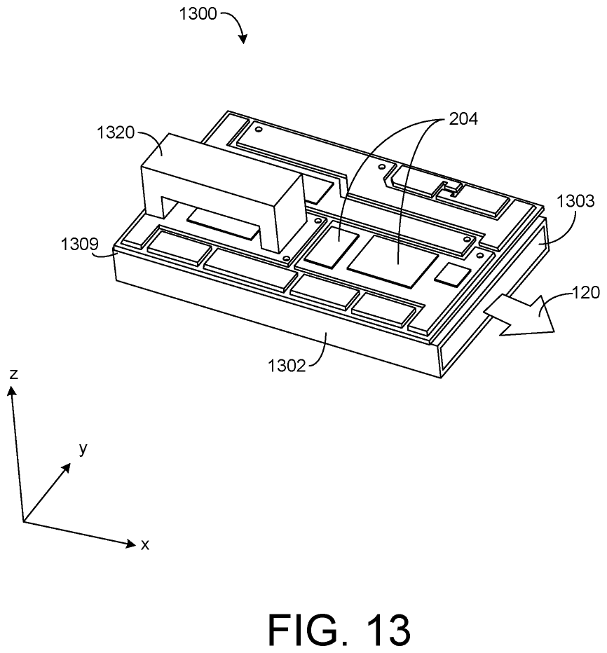

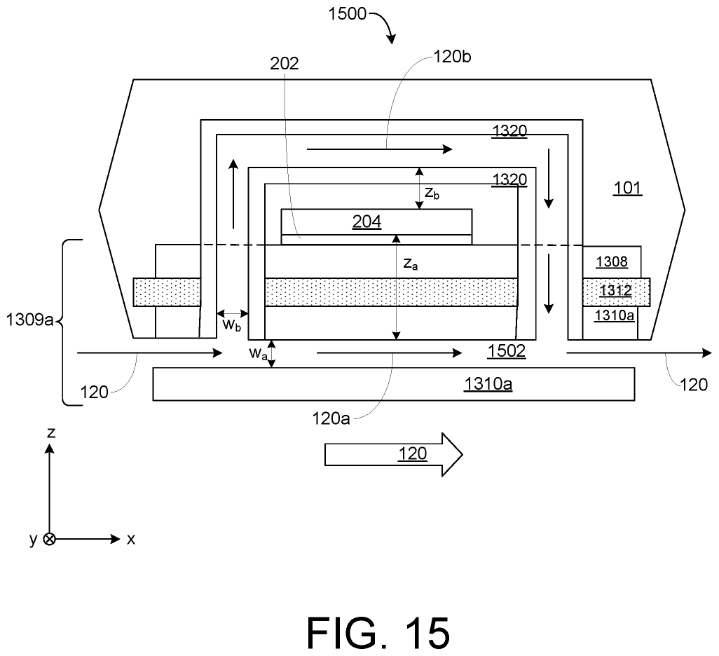

FIG. 13 is an exterior perspective view of a fluid-cooled power module 1300, in accordance with some implementations of the present disclosure. The fluid-cooled power module 1300 includes a semiconductor device module mounted on, e.g., attached to, a heat dissipation structure 1302. The semiconductor device module is shown unencapsulated in FIG. 13. In some implementations, the semiconductor device module is a high power semiconductor device module that features a fluid-cooled DBM structure 1309 and a cooler pipe 1320. The DBM structure 1309 supports chip assemblies 204 and the cooler pipe 1320. In some implementations, the cooler pipe 1320 is a U-shaped enclosure that provides a fluid channel that will extend into the encapsulant 101 as shown in FIGS. 15-17. The cooler pipe 1320 can have curved walls or straight sided walls, or combinations thereof. Walls of the cooler pipe 1320 can include one or more metals, e.g., copper or aluminum. The cooler pipe 1320 can be attached to the fluid-cooled DBM structure 1309 during a package assembly process.

The heat dissipation structure 1302 provides containment for flow of a cooling fluid, e.g., a water jacket, wherein the flow direction is indicated by the arrow 120. A slot 1303 in the end of the heat dissipation structure 1302 is shown in FIG. 13, through which the cooling fluid can flow during operation of the fluid-cooled power module 1300. In some implementations as shown in FIGS. 15-17 and as described below, the cooling fluid can be channeled to flow from the heat dissipation structure 1302 along various routes through portions of the fluid-cooled DBM structure 1309 and the cooler pipe 1320.

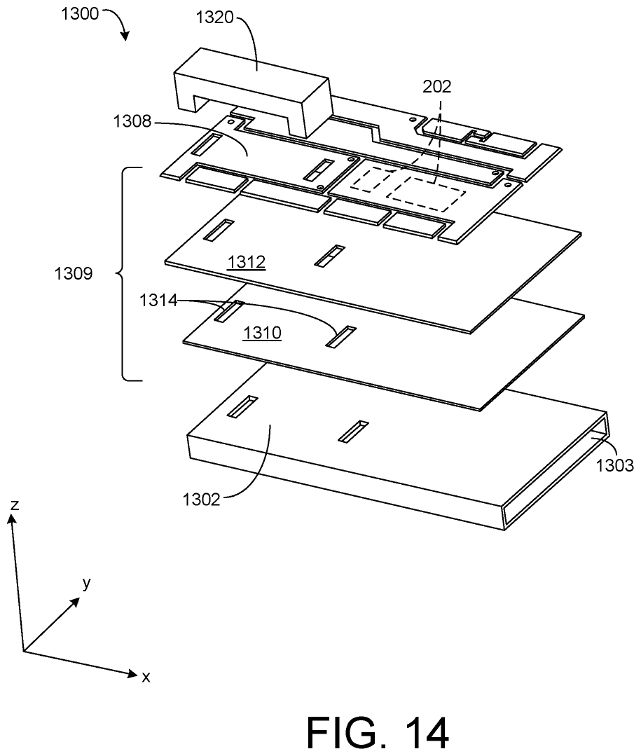

FIG. 14 is an exploded view of the fluid-cooled DBM structure 1309, in accordance with some implementations of the present disclosure. The fluid-cooled DBM structure 1309 includes a first conductive layer 1308, a second conductive layer 1310, and a non-conductive layer 1312, e.g., a middle ceramic layer. Each of the layers of the fluid-cooled DBM structure 1309 includes slots 1314 to accommodate vertical flow of cooling fluid. In some implementations, the slots 1314 may accommodate and secure vertical members, e.g., legs, of the cooler pipe 1320, which may extend through the slots 1314 in the layers of the fluid-cooled DBM structure 1309. In some implementations, cooling fluid may flow through the slots while the cooler pipe 1320 attaches to the first conductive layer 1308 to guide circulation of the cooling fluid. The slots 1314 in the various layers of the fluid-cooled DBM structure 1309 can be formed by a via etching process. In some implementations, the slots 1314 can be lined with a metal material, e.g., a material similar to that of the cooler pipe 1320. The first conductive layer 1308 can be further patterned and etched to form die attach pads 202 to receive the chip assemblies 204.

FIG. 15 is a cross-sectional view of a semiconductor device module 1500, in accordance with some implementations of the present disclosure. The semiconductor device module 1500 includes a fluid-cooled DBM structure 1309a as a possible implementation of the fluid-cooled DBM structure 1309 shown in FIG. 14. The fluid-cooled DBM structure 1309a includes a second conductive layer 1310a as a possible implementation of the second conductive layer 1310. The second conductive layer 1310a can be thicker than the first conductive layer 1308 to accommodate a fluid channel.

The semiconductor device module 1500 further includes the cooler pipe 1320 shown in FIGS. 13 and 14. The fluid-cooled DBM structure 1309a and the cooler pipe 1320 provide internal cooling by routing the cooling fluid through multiple channels to pipe cooling fluid around all sides of the chip assemblies 204. In some implementations, the semiconductor device module 1500 can include a first channel 1502 through the second conductive layer 1310a that provides the direct flow path 120a, and a second, U-shaped channel that extends upward through the second conductive layer 1310a, the non-conductive layer 1312, and the first conductive layer 1308 into the encapsulant 101 that provides the indirect flow path 120b. In some implementations, the entire U-shaped channel can be formed by the cooler pipe 1320. In some implementations, as indicated by the dashed line, the cooler pipe 1320 can form an upper portion of the U-shaped channel above the dashed lines, while the slots 1314 can form lower portions of the U-shaped channel, below the dashed lines.

The general direction of fluid flow through the fluid-cooled DBM structure 1309a and the cooler pipe 1320 is shown by the arrow 120. In some implementations, a first portion of the cooling fluid can be routed horizontally in the +x direction, along a substantially direct flow path 120a through the first channel 1502 through the second conductive layer 1310a. A second portion of the cooling fluid can be routed around a indirect flow path 120b through the encapsulant 101. The indirect flow path 120b is provided by the second channel formed by the cooler pipe 1320. Accordingly, the second portion of the cooling fluid initially flows along a horizontal path in the +x direction to enter the second conductive layer 1310. The second portion of the cooling fluid can then be diverted upward along a vertical member of the cooler pipe 1320 in the +z direction, passing through the fluid-cooled DBM structure 1309a into the encapsulant 101. The second portion of the cooling fluid can then flow horizontally in the +x direction above the chip assemblies 204, and then downward in the −z direction through a vertical member of the cooler pipe 1320 to join with the first portion. Both portions of the cooling fluid can then flow together, horizontally in the +x direction, to exit the semiconductor device module 1500 through the first channel 1502 in the second conductive layer 1310a. As the cooling fluid absorbs heat along its flow paths, and then exits the semiconductor device module 1500, the cooling fluid carries heat out of the fluid-cooled DBM structure 1309a and the cooler pipe 1320, thus cooling the semiconductor device module 1500.

Because the second portion of the cooling fluid is diverted to flow horizontally through the cooler pipe 1320 within the encapsulant 101, the second portion is brought in close proximity, e.g., at a short vertical distance z_{b} to the chip assemblies 204. Consequently, the second portion of the cooling fluid can absorb more heat generated by the chip assemblies 204 than the first portion can absorb at a long vertical distance zₐ from the chip assemblies 204 while flowing through the first channel 1502. Thus, splitting the flow path to bring some of the cooling fluid closer to the chip assemblies 204, e.g., along the indirect flow path 120b through the encapsulant 101 will cool the semiconductor device module 1500 more quickly and efficiently than flowing all of the cooling fluid along the direct flow path 120a, through the first channel 1502. By adjusting the height of the cooler pipe 1320 to reduce the vertical distance z_{b}, the cooling efficiency of the semiconductor device module 1500 can be further increased.

A volume of cooling fluid, e.g., an amount of the second portion, that enters the cooler pipe 1320, relative to the volume of cooling fluid, e.g., an amount of the first portion, that enters the first channel 1502, can be influenced by the relative widths of the two channels, e.g., a channel width wₐ of the first channel 1502 relative to a channel width w_{b} of the cooler pipe 1320. In some implementations, the channel width w_{b} of the cooler pipe 1320 can be about the same scale as the die width, e.g., about 0.5 mm. In some implementations, the length of the cooler pipe 1320 is about the same scale as the die length, e.g., about half the length of the DBM. In some implementations, an area of the cooler pipe 1320 covers at least half the area of the DBM. When w_{b} is wider than wₐ, the second portion of the cooling fluid that flows along the indirect flow path 120b in the cooler pipe 1320 may be larger, e.g., by volume, than the first portion of the cooling fluid that flows through the first channel 1502. In some implementations, when w_{b} is wider than wₐ a flow rate of the second portion within the cooler pipe 1320 can exceed a flow rate of the first portion within the first channel 1502. By either increasing the flow rate or the volume of the second portion relative to the first portion, the cooling efficiency of the semiconductor device module 1500 can be increased.

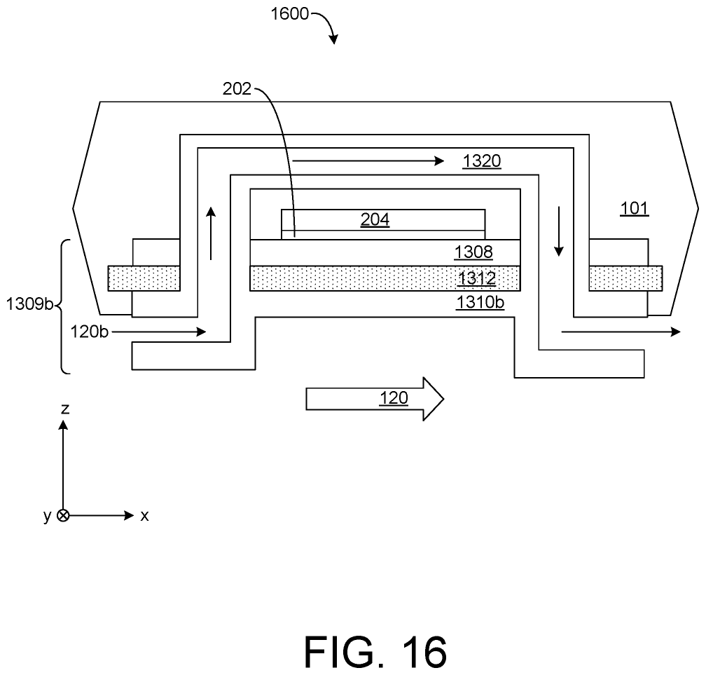

FIG. 16 is a cross-sectional view of a semiconductor device module 1600, in accordance with some implementations of the present disclosure. The semiconductor device module 1600 includes a fluid-cooled DBM structure 1309b as a possible implementation of the fluid-cooled DBM structure 1309 shown in FIG. 14. The fluid-cooled DBM structure 1309b includes a second conductive layer 1310b as a possible implementation of the second conductive layer 1310. Similar to the semiconductor device module 1500 shown in FIG. 15, the semiconductor device module 1600 also provides internal cooling by piping cooling fluid through the encapsulant 101, around all sides of the chip assemblies 204. However, instead of splitting the cooling fluid into two portions along different flow paths within two different channels, in the semiconductor device module 1600, all of the cooling fluid is routed through the indirect flow path 120b through the cooler pipe 1320. The second conductive layer 1310b therefore can be thinner than the second conductive layer 1310a used in the semiconductor device module 1500, since the second conductive layer 1310b does not need to accommodate a fluid channel.

The indirect flow path 120b through the fluid-cooled DBM structure 1309b is provided by a U-shaped channel in the form of the cooler pipe 1320 that extends upward through the second conductive layer 1310b, the non-conductive layer 1312, and the first conductive layer 1308 into the encapsulant 101. The cooling fluid can be routed initially along a horizontal section of a flow path in the +x direction to enter the second conductive layer 1310b. The cooling fluid can then be directed upward in the +z direction through the fluid-cooled DBM structure 1309b, within a vertical member of the cooler pipe 1320, then horizontally in the +x direction above the chip assemblies 204, and then downward in the −z direction through a vertical member of the cooler pipe 1320, and then horizontally in the +x direction to exit the semiconductor device module 1600. As the cooling fluid absorbs heat along its circuitous flow path 120b through the cooler pipe 1320, the cooling fluid carries heat out of the encapsulant 101, thus cooling the semiconductor device module 1600.

Because all of the cooling fluid is directed to flow through encapsulant 101 while contained in the cooler pipe 1320, a full volume of the cooling fluid is brought in close proximity to three sides of the chip assemblies 204. Consequently, the cooling fluid can absorb more heat generated by the chip assemblies 204 than if some of the cooling fluid was routed farther away from the chip assemblies 204. Thus, the configuration shown in FIG. 16 would be expected to cool the semiconductor device module 1600 more quickly and efficiently than routing only a portion of the cooling fluid close to the chip assemblies 204 as in other configurations.

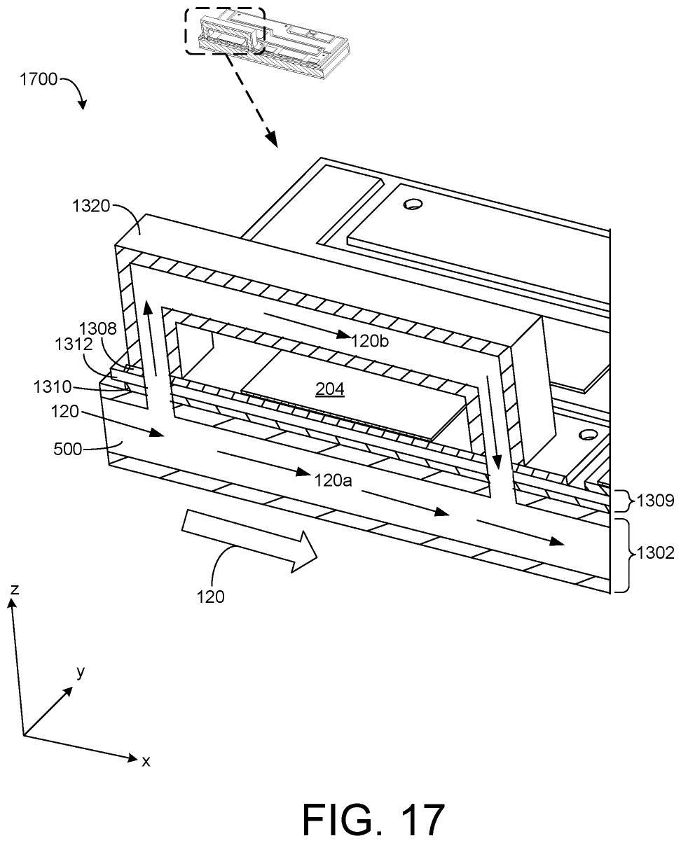

FIG. 17 is a cross-sectional view of a fluid-cooled power module 1700, in accordance with some implementations of the present disclosure. The fluid-cooled power module 1700 is a possible implementation of the fluid-cooled power module 1300 shown in FIG. 13. The cross-sectional view shows interior elements of the fluid-cooled DBM structure 1309 and interior elements of the heat dissipation structure 1302. The first conductive layer 1308 of the fluid-cooled DBM structure 1309 is patterned e.g., by etching, so that remaining portions of the first conductive layer 1308 support the chip assemblies 204. FIG. 17 shows the cooling fluid 502 entering the heat dissipation structure 1302 along a path 120. A first portion of the cooling fluid 502 flows along a direct flow path 120a through the heat dissipation structure 1302, while a second portion of the cooling fluid 502 flows along a indirect flow path 120b through the fluid-cooled DBM structure 1309. The indirect flow path 120b directs the second portion through the cooler pipe 1320, which forms a U-shaped channel. The fluid paths shown in FIG. 17 are similar to those shown in FIG. 15, except the direct flow path 120a in FIG. 11 is through the heat dissipation structure 1302, whereas the direct flow path 120a in FIG. 15 is within the second conductive layer 1310a.

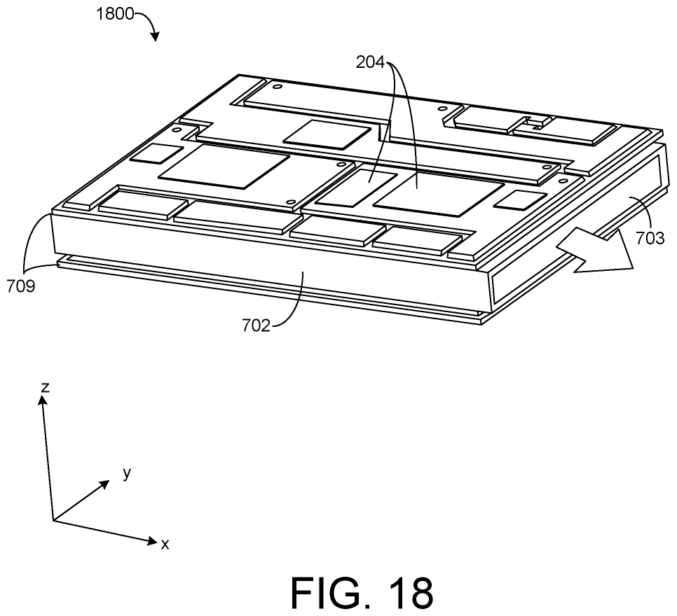

FIG. 18 is a cross-sectional view of a double-sided fluid-cooled power module 1800, in accordance with some implementations of the present disclosure. The double-sided fluid-cooled power module 1800 is similar to the fluid-cooled power module 700, with a second fluid-cooled DBM structure 709 attached to the underside of the heat dissipation structure 702. In some implementations, the second conductive layer of the second fluid-cooled DBM structure 709 can be attached to the heat dissipation structure 702 and the first conductive layer, e.g., the patterned metal layer, can face downward so that additional chip assemblies 204 can be mounted on a lower surface of the double-sided fluid-cooled power module 1800.

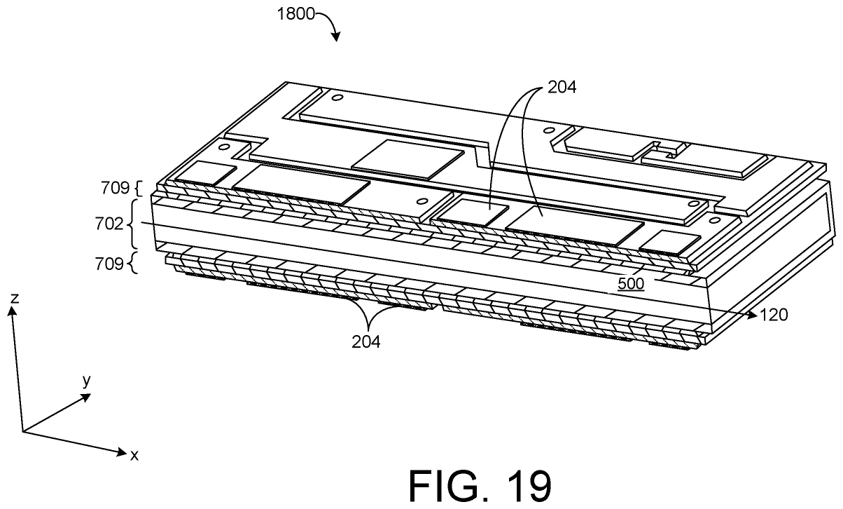

FIG. 19 is a magnified cross-sectional view of the double-sided fluid-cooled power module 1800 shown in FIG. 18, in accordance with some implementations of the present disclosure. FIG. 19 shows a first fluid-cooled DBM structure 709 attached to a top surface of the heat dissipation structure 702, and a second fluid-cooled DBM structure 709 attached to a bottom surface of the heat dissipation structure 702. Three layers are shown within the first fluid-cooled DBM structure 709 and the second fluid-cooled DBM structure 709. The cooling fluid 502 within the heat dissipation structure 702 is also shown in FIG. 19. Chip assemblies 204 are shown mounted on the patterned first conductive layer of the first fluid-cooled DBM structure 709 and the patterned first conductive layer of the second fluid-cooled DBM structure 709.

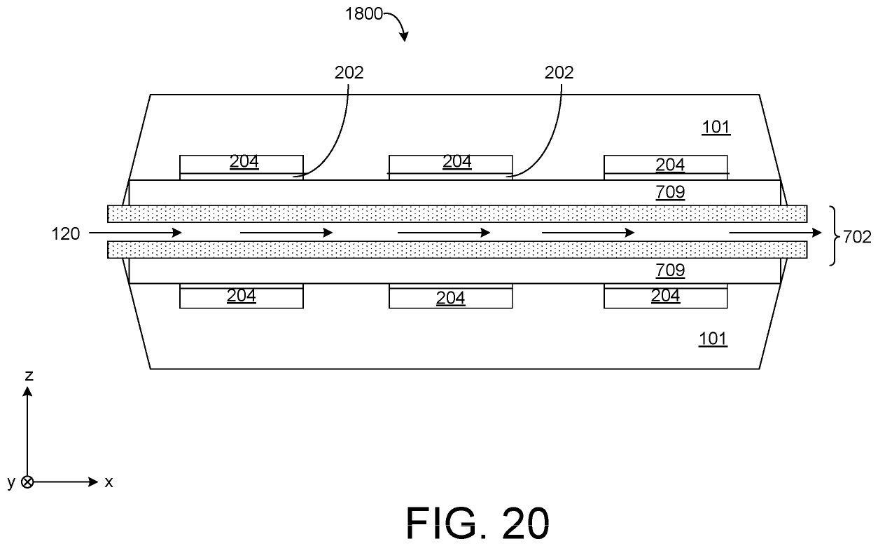

FIG. 20 is a cross-sectional view of the double-sided fluid-cooled power module 1800, in accordance with some implementations of the present disclosure. The double-sided fluid-cooled power module 1800 has, at its center, the heat dissipation structure 702, which provides a channel for the flow of cooling fluid in the +x direction, as indicated by the arrow 120. In some implementations, a first fluid-cooled DBM structure 709 is mounted on an upper surface of the heat dissipation structure 702 and a second fluid-cooled DBM structure 709 is mounted on a lower surface of the heat dissipation structure 702. An array of chip assemblies 204 can then be mounted on the die attach pads 202 formed by the first conductive layer of each fluid-cooled DBM structure 709. The chip assemblies 204 and the first and second fluid-cooled DBM structures 709 can then be packaged together using the encapsulant 101. With the double-sided fluid-cooled power module 1800, cooling fluid moving through the central heat dissipation structure 702 can provide thermal control for many more, e.g., double the number of chip assemblies 204 within the same package, than could be accommodated using a single-sided cooling configuration.

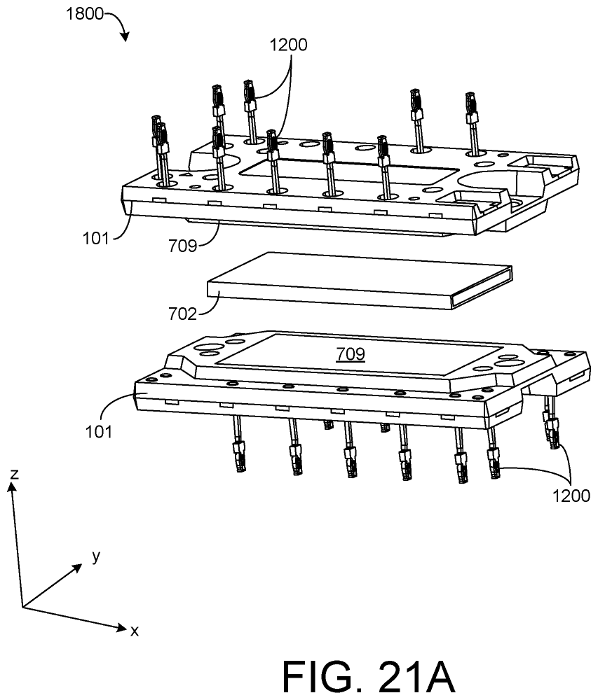

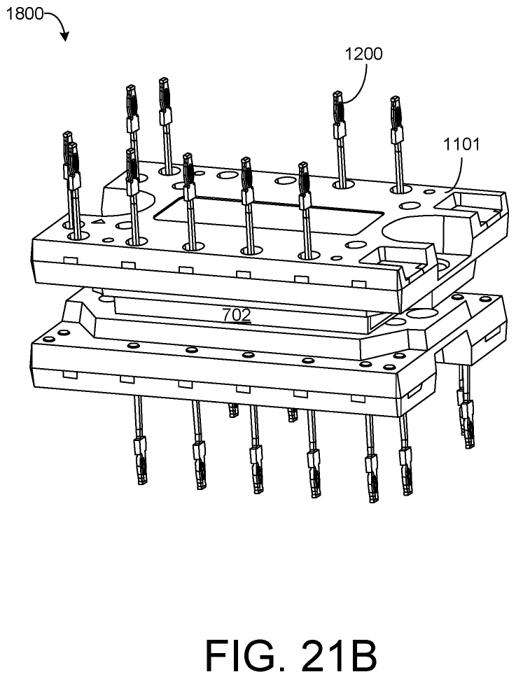

FIG. 21A is an exploded view of the double-sided fluid-cooled power module 1800 following packaging in the encapsulant 101, in accordance with some implementations of the present disclosure. The encapsulant 101, e.g., an epoxy molding compound (EMC), can be injection-molded or otherwise formed around the first fluid-cooled DBM structure 709. A mirror image of the encapsulant 101 can be similarly formed around the second fluid-cooled DBM structure 709. The encapsulant 101 has an opening so that the second conductive layer of the first fluid-cooled DBM structure 709 and the second conductive layer of the second fluid-cooled DBM structure 709 are both exposed for direct contact with the heat dissipation structure 702. In some implementations, the first and second DBM structures 709 are not connected electrically. The encapsulant does not surround the heat dissipation structure 702, thus allowing the cooling fluid to flow into and out of the ends of the heat dissipation structure 702. The heat dissipation structure 702 thus provides cooling for separate top and bottom packages simultaneously, which reduces the overall system size. Outside surfaces of the encapsulant 101 include openings through which the connection pins 1200 can extend to provide external electrical connections to the chip assemblies 204. FIG. 21B shows a final configuration of the double-sided fluid-cooled power module 1800, in which the packaged semiconductor device modules have both been joined to the heat dissipation structure 702.

As described above, various implementations of a fluid-cooled power module for use in high power applications are structured to interact with a cooling fluid to improve thermal performance, increase reliability, and reduce package size and/or cost. In some implementations, the addition of various fin structures has been shown to increase efficiency of the cooling fluid in transporting heat away from the chip assemblies 204. In some implementations, the flow of cooling fluid can be routed through channels or pipes to bring the fluid in close proximity to the chip assemblies 204, thereby improving cooling efficiency. Double-sided fluid cooling can double the density of dies within each power module.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A device, comprising:
a fluid-cooled direct bonded metal structure, including:
a first conductive layer,
a second conductive layer, configured to support a flow of cooling fluid in contact with a surface area of the second conductive layer, and
a non-conductive layer disposed between the first conductive layer and the second conductive layer;
a heat sink coupled to the second conductive layer;
a semiconductor die coupled to the fluid-cooled direct bonded metal structure; and
a molding compound surrounding the semiconductor die and a portion of the fluid-cooled direct bonded metal structure.

2. The device of claim 1, wherein the heat sink is part of a detachable cooling unit.

3. The device of claim 1, further comprising a side heat slug coupling the second conductive layer to the first conductive layer.

4. The device of claim 1, wherein the heat sink includes a base plate and a plurality of oblique fins extending out from the base plate at an acute angle.

5. The device of claim 1, wherein the heat sink includes a base plate and a plurality of L-shaped fins extending out from the base plate at an acute angle.

6. A device, comprising:
a fluid-cooled direct bonded metal structure configured with a channel, the fluid-cooled direct bonded metal structure including:
a first conductive layer,
a non-conductive layer, and
a second conductive layer;
a semiconductor die mounted on the fluid-cooled direct bonded metal structure; and
a molding compound surrounding the semiconductor die and a portion of the fluid-cooled direct bonded metal structure.

7. The device of claim 6, wherein the channel provides a first flow path through the second conductive layer.

8. The device of claim 7, wherein the channel further provides a second flow path through the non-conductive layer.

9. The device of claim 8, wherein the non-conductive layer includes a top ceramic plate and a bottom ceramic plate in which the channel is formed.

10. The device of claim 7, wherein the channel further provides a second flow path through the molding compound to surround the semiconductor die.

11. The device of claim 10, further comprising a U-shaped cooler pipe that provides a structure for the second flow path.

12. The device of claim 6, wherein the channel provides a single flow path through the second conductive layer and through the non-conductive layer.

13. The device of claim 6, wherein the channel provides a single flow path through the second conductive layer and through the molding compound to surround the semiconductor die.

14. The device of claim 6, wherein the channel provides a single flow path through the non-conductive layer.

15. The device of claim 6, wherein the semiconductor dies are mounted to at least one of the first conductive layer and the second conductive layer.

16. A cooling unit, comprising:
a heat sink including an array of fins having a metal surface area, the array of fins configured to support a flow of cooling fluid in contact with the metal surface area; and
a fluid container surrounding the heat sink.

17. The cooling unit of claim 16, wherein the fins are L-shaped.

18. The cooling unit of claim 16, wherein the fluid container includes aluminum.

19. The cooling unit of claim 16, wherein the fluid container has the shape of a rectangular box.

20. The cooling unit of claim 16, wherein a top surface of the cooling unit is configured with metal traces to receive a semiconductor module.
